(19) United States
(12) Patent Application Publication
(10) Pub. No.: US 2012/0220107 A1
(43) Pub. Date: Aug. 30, 2012

(54) SUBSTRATE PROCESSING APPARATUS, WAFER HOLDER, AND METHOD OF MANUFACTURING SEMICONDUCTOR DEVICE

(75) Inventors: Masanao Fukuda, Toyama (JP); Takafumi Sasaki, Toyama (JP); Takatomo Yamaguchi, Toyama (JP); Daisuke Hara, Toyama (JP)

(73) Assignee: HITACHI KOKUSAI ELECTRIC INC., Tokyo (JP)

(21) Appl. No.: 13/405,638

(22) Filed: Feb. 27, 2012

(30) Foreign Application Priority Data
Feb. 28, 2011 (JP) 2011-041214

(51) Int. Cl. H01L 21/20; B65D 85/00; C30B 25/12

(52) U.S. Cl. 438/478; 118/728; 206/710; 257/E21.09

(57) ABSTRACT

Provided is a substrate processing apparatus having a stack structure of wafers that can endure a high temperature without bad influence on film-forming precision. The stack structure includes a holder base (110) configured to hold a wafer (14) at an inner circumference side thereof, and boat columns (31a to 31c) each including a holder retainer (HS) configured to hold an outer circumference side of the holder base (110), wherein an outer diameter of the holder base (110) is larger than that of the wafer (14), and the holder base (110) is detachable from the holder retainers (HS).

### CROSS-REFERENCE TO RELATED PATENT APPLICATION

This U.S. non-provisional patent application claims priority under 35 U.S.C. §119 of Japanese Patent Application No. 2011-041214, filed on Feb. 28, 2011, in the Japanese Patent Office, the entire contents of which are hereby incorporated by reference.

### BACKGROUND OF THE INVENTION

1. Field of the Invention

The present invention relates to a substrate processing apparatus for processing a plurality of stacked substrates, a wafer holder and a method of manufacturing a substrate or a semiconductor device, and more particularly, to a substrate processing apparatus for forming a silicon carbide (SiC) epitaxial film on a substrate, a wafer holder and a method of manufacturing a substrate or a semiconductor device.

2. Description of the Related Art

Since silicon carbide (SiC) has a higher withstand voltage or thermal conductivity than silicon (Si), SiC is attracting attention as a device material for, in particular, a power device. Meanwhile, as is well known in the art, since SiC has a small impurity diffusion coefficient, manufacture of a crystalline substrate or a semiconductor device is difficult in comparison with Si. For example, since an epitaxial film-forming temperature of SiC is about 1,500° C. to 1,800° C. in comparison with Si having an epitaxial film-forming temperature of about 900° C. to 1,200° C., technical research on a heat-resistant structure of an apparatus or suppression of decomposition of a material is needed.

As a batch-type substrate processing apparatus that can efficiently process a plurality of substrates, for example, a batch-type vertical substrate processing apparatus including a boat configured to hold and stack a plurality of substrates in a longitudinal direction thereof is already known. The batch-type vertical substrate processing apparatus conveys the boat in which the plurality of substrates are stacked and held into a processing furnace, and then, increases a temperature in the processing furnace to a predetermined temperature to supply a reactive gas toward the substrates through a gas nozzle installed in the processing furnace. Accordingly, since film-forming surfaces of the substrates are exposed to the reactive gas, the batch-type vertical substrate processing apparatus can efficiently perform the film-forming processing of the substrates at once.

As the batch-type vertical substrate processing apparatus, for example, techniques disclosed in Patent Documents 1 and 2 are known.

The substrate processing apparatus disclosed in Patent Document 1 includes a boat in which a plurality of wafers (substrates) are stacked and held, and holder plates having an annular shape and formed of quartz are welded to a plurality of columns constituting the boat in a horizontal posture in a multi-stage. In addition, three claws are fixed to a radial inside (an inner circumference) of each holder plate by welding, and each of the claws functions to hold a wafer in a horizontal posture. A reactive gas introduction pipe (a gas nozzle) is installed at a radial outside of the holder plate, and a reactive gas supplied through the reactive gas introduction pipe passes through each column portion from the radial outside to arrive at each wafer. Since each column is exposed to the reactive gas, the column is also coated with a film. That is, since each column consumes the reactive gas, a film-forming element concentration of the reactive gas around each column becomes low. In this regard, in the substrate processing apparatus disclosed in Patent Document 1, since a distance between each column and each wafer is increased, a certain concentration of reactive gas is substantially supplied to a film-forming surface of each wafer to suppress bad influence on film-forming precision.

In the substrate processing apparatus disclosed in Patent Document 2, circumferential wafer supports are fixed to a plurality of columns constituting a boat by welding, etc., and a wafer (a substrate) is supported by each of the wafer supports. In addition, as described above, in consideration of consumption of the reactive gas by the columns as described above, a ring-shaped plate having cutout portions corresponding to the columns is fixed to the columns by welding, etc. Accordingly, the columns corresponding to the cutout portions and a portion of the ring-shaped plate, outside of the cutout portions, consume the reactive gas, and further, a certain concentration of reactive gas is substantially supplied to a film-forming surface of each wafer to suppress bad influence on film-forming precision.

### RELATED ART DOCUMENTS

### Patent Documents

1. Japanese Patent Laid-open Publication No. H11-040509

2. International Publication No. 2005/053016 Pamphlet

### SUMMARY OF THE INVENTION

However, according to the substrate processing apparatuses disclosed in Patent Documents 1 and 2, a plurality of members such as the holder plates, wafer supports and ring-shaped plates are fixed to the columns (boat columns) by welding, etc., to thereby form a boat made of quartz. For this reason, when the boat made of quartz is used under a high temperature of more than 1,000° C. as it is, the boat may be melted. Accordingly, there was a need to separately develop a boat having a heat-resistant structure that can withstand an epitaxial film-forming temperature (about 1,500° C. to 1,800° C.) of SiC. While the boat may be manufactured by fixing the plurality of members using a material having good heat-resistance such as SiC, the material such as SiC cannot be easily fixed by welding as the heat resistance is increased. That is, instead of manufacture of the conventional boat by simply changing the material with a material having good heat resistance, review of a stack structure of wafers with respect to the boat is becoming necessary.

It is an aspect of the present invention to provide a substrate processing apparatus, a wafer holder and a method of manufacturing a semiconductor device having a stack structure of wafers that can endure a high temperature, without bad influence on film-forming precision.

The above and other aspects and novel features of the present invention will be apparent from the detailed description and the accompanying drawings of the specification.

Summaries of the present invention obtained by typical embodiments will be described in brief as follows.

That is, a substrate processing apparatus in accordance with the present invention includes: a reaction vessel; a gas nozzle installed in the reaction vessel and configured to supply a reactive gas into the reaction vessel; a boat including a plurality of boat columns having holder retainers, the boat being configured to be loaded into and unloaded from the reaction vessel; and a wafer holder held by the holder retainers, an inner circumference side of the wafer holder supporting a substrate, wherein an outer diameter of the wafer holder is larger than that of the substrate and the wafer holder is detachable from the holder retainers.

In addition, a wafer holder in accordance with the present invention is transferred to a boat including a plurality of boat columns having holder retainers to be held by the holder retainers, and configured to hold a substrate at an inner circumference side thereof, wherein an outer diameter of the wafer holder is larger than that of the substrate and the wafer holder is detachable from the holder retainers.

Further, a method of manufacturing a semiconductor device in accordance with the present invention uses a substrate processing apparatus including a reaction vessel; a gas nozzle installed in the reaction vessel and configured to supply a reactive gas into the reaction vessel; a boat including a plurality of boat columns having holder retainers, the boat being configured to be loaded into and unloaded from the reaction vessel; and a wafer holder held by the holder retainers, an inner circumference side of the wafer holder supporting a substrate, wherein an outer diameter of the wafer holder is larger than that of the substrate and the wafer holder is detachable from the holder retainers, and includes: loading the boat, in which the wafer holder holding the substrate is held by the holder retainers, into the reaction vessel; supplying the reactive gas into the reaction vessel through the gas nozzle to form a film on a surface of the substrate; and unloading the boat from the reaction vessel, wherein an outer diameter of the wafer holder is larger than that of the substrate, and the wafer holder is detachable from the holder retainers.

### Effects of the Invention

Effects of the present invention obtained by typical embodiments will be described in brief as follows.

That is, a stack structure of wafers that can endure a high temperature can be obtained, without bad influence on film-forming precision.

### BRIEF DESCRIPTION OF THE DRAWINGS

FIG. 1 is a perspective view schematically showing a substrate processing apparatus in accordance with the present invention;

FIG. 2 is a cross-sectional view showing an internal structure of a processing furnace;

FIG. 3 is a cross-sectional view showing a peripheral structure of the processing furnace;

FIG. 4 is a block diagram for explaining a control system of the substrate processing apparatus;

FIG. 5 is a perspective view showing a detailed structure of a boat;

FIG. 6 is a cross-sectional view showing a state in which a wafer is held by a wafer holder;

FIG. 7 is a perspective view showing the wafer and the wafer holder;

FIG. 8 is a view for explaining consumption of a reactive gas at the wafer holder;

FIG. 9 is a perspective view showing a wafer holder (Comparative example) having a simple annular shape, corresponding to FIG. 7;

FIG. 10 is an analysis view showing a film-forming state of a wafer using the wafer holder in accordance with Comparative example of FIG. 9;

FIG. 11 is an analysis view showing a film-forming state of a wafer using the wafer holder in accordance with the present invention;

FIG. 12 is a perspective view showing a wafer holder in accordance with a second embodiment, corresponding to FIG. 7;

FIG. 13 is a view for explaining consumption of a reactive gas at the wafer holder of FIG. 12; and

FIG. 14 is an exemplary flowchart of a method of manufacturing a semiconductor device in accordance with the present invention.

### DETAILED DESCRIPTION OF THE PREFERRED EMBODIMENTS

### First Embodiment

Hereinafter, an exemplary embodiment of the present invention will be described with reference to the accompanying drawings. In the embodiment described below, a SiC epitaxial growth apparatus, which is an example of a substrate processing apparatus, is known to as a batch type vertical SiC epitaxial growth apparatus in which SiC wafers are arranged in a vertical direction (a longitudinal direction). Accordingly, the number of SiC wafers that can be processed at a time is increased to improve throughput (manufacturing efficiency).

<Entire Configuration>

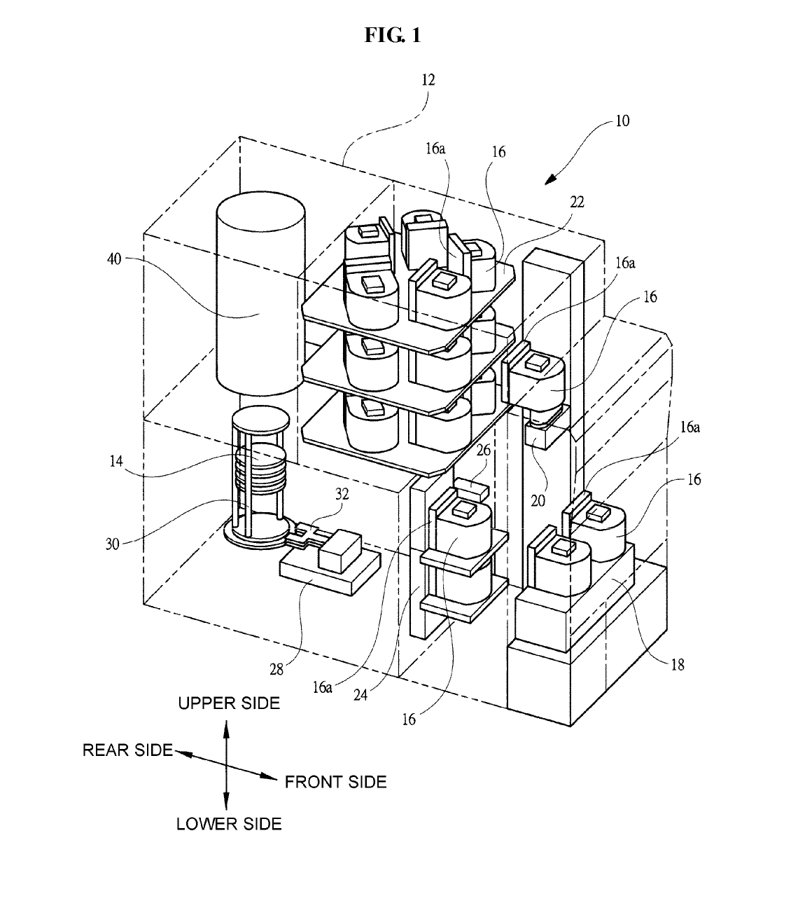

FIG. 1 is a perspective view schematically showing a substrate processing apparatus in accordance with the present invention. First, a substrate processing apparatus for forming a SiC epitaxial film and a method of manufacturing a substrate for forming a SiC epitaxial film, one of semiconductor device manufacturing processes, of an embodiment of the present invention will be described with reference to FIG. 1.

A semiconductor manufacturing apparatus 10, which is a substrate processing apparatus (a film-forming apparatus), is a batch-type vertical thermal processing apparatus and includes a housing 12 configured to accommodate a plurality of apparatuses having various functions. In the semiconductor manufacturing apparatus 10, as a substrate accommodating vessel configured to receive a wafer 14, which is a substrate formed of SiC, a pod (FOUP) 16 is used as a wafer carrier.

A pod stage 18 is installed in the front of the housing 12, and the pod 16 is conveyed onto the pod stage 18. For example, 25 wafers 14 are received in the pod 16, and the pod 16 is set on the pod stage 18 in a state in which a cover 16a is closed (in a closed state).

A pod conveyance apparatus 20 is installed in the front of the housing 12 and a rear side of the pod stage 18 to oppose the pod stage 18. In addition, a multi-stage (three stages in the drawing) of pod accommodating shelves 22, a pod opener 24 and a substrate number detector 26 are installed adjacent to and at a rear side of the pod conveyance apparatus 20. Each of the pod accommodating shelves 22 is installed above the pod opener 24 and the substrate number detector 26, and configured to mount a plurality of pods 16 (five pods in the drawing) to maintain the state. The pod conveyance apparatus 20 sequentially conveys the pods 16 between the pod stage 18, each of the pod accommodating shelves 22 and the pod opener 24. The pod opener 24 opens the cover 16a of the pod 16, and the substrate number detector 26 is installed adjacent to the pod opener 24 to detect the number of wafers 14 in the pod 16 with the cover 16a open.

In addition, a substrate transfer apparatus 28 and a boat 30, which is a substrate holding member, are installed in the housing 12. The substrate transfer apparatus 28 includes, for example, five arms (tweezers) 32, and each of the arms 32 has a structure that can be lifted and rotated by a driving means (not shown) so that five wafers 14 can be extracted from the pod 16 at a time. In addition, as each of the arms 32 is reversely moved from a front side to a rear side, the wafers 14 can be conveyed from the pod 16 disposed at a position of the pod opener 24 toward the boat 30 five at a time.

A processing furnace 40 is installed at a rear and upper side in the housing 12. The boat 30 in which the plurality of wafers 14 are loaded is loaded into the processing furnace 40, and thus, the plurality of stacked wafers 14 can be thermally processed (batch-processed) at once.

<Configuration of Processing Furnace>

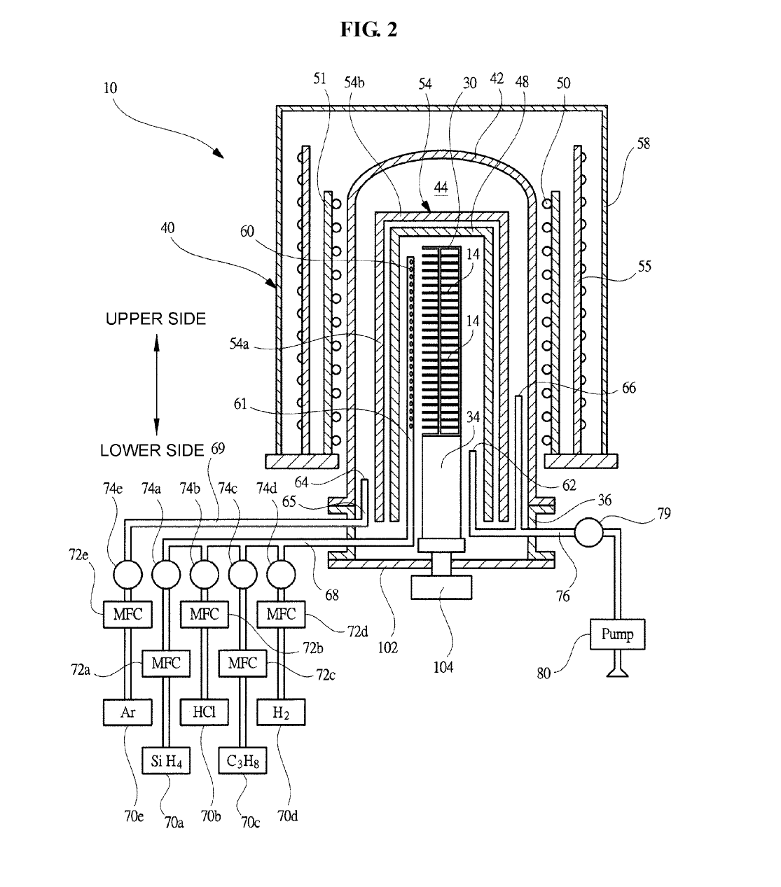

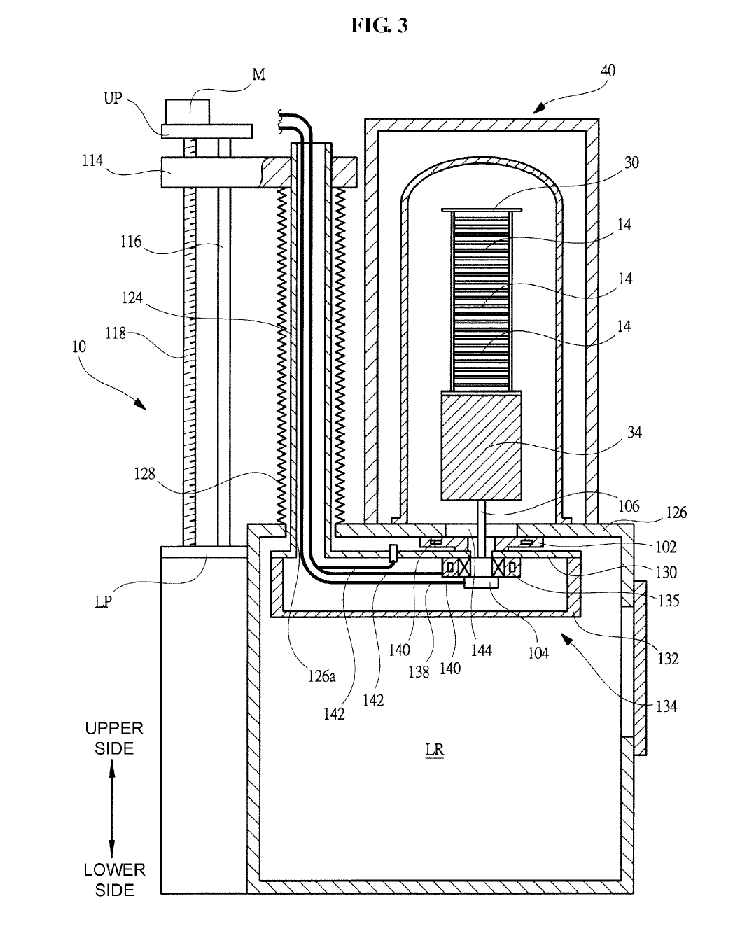

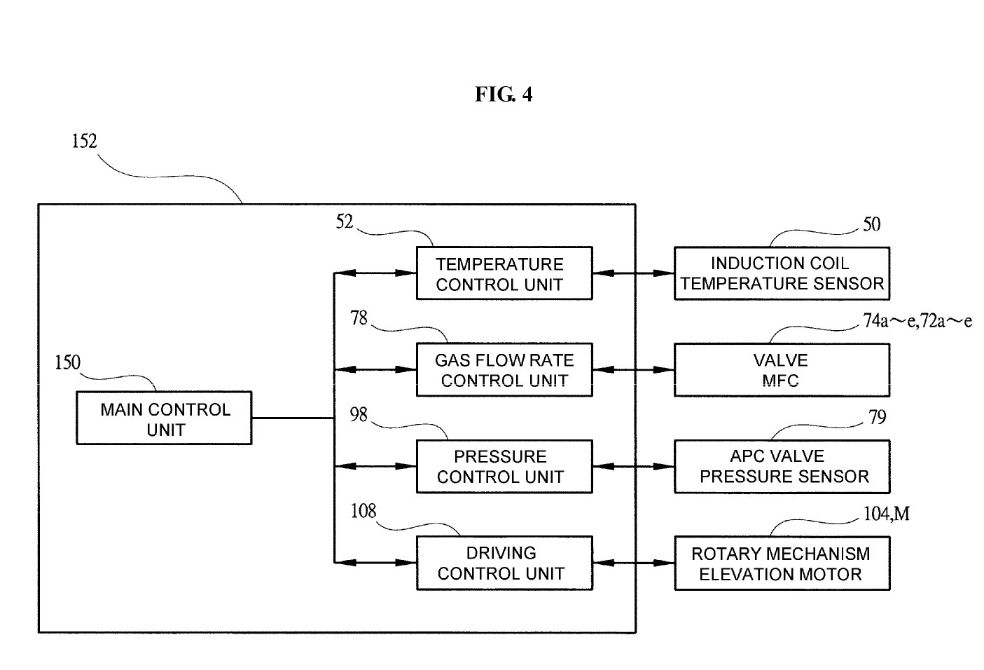

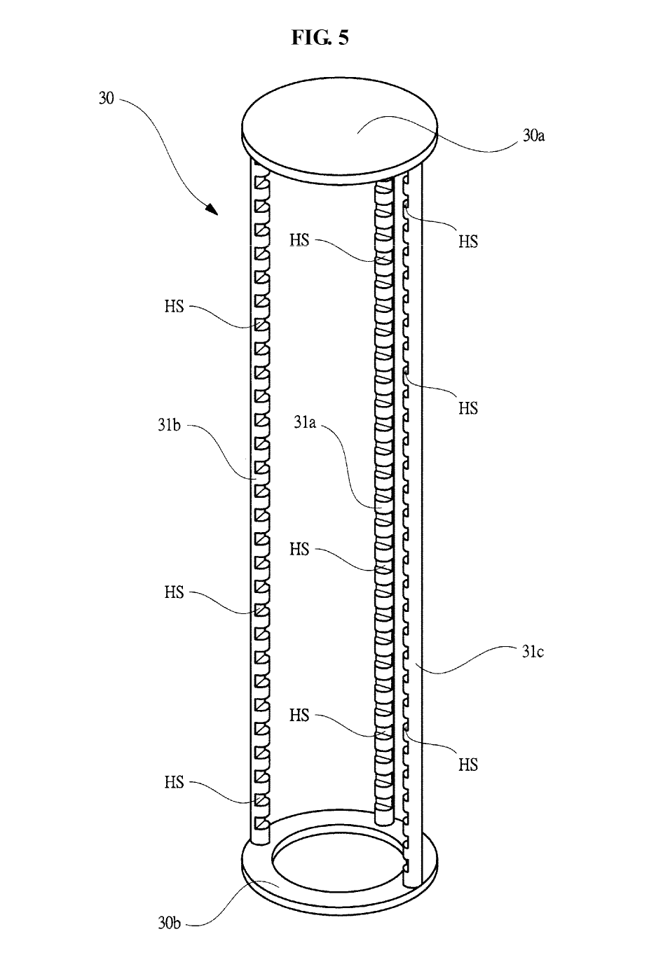

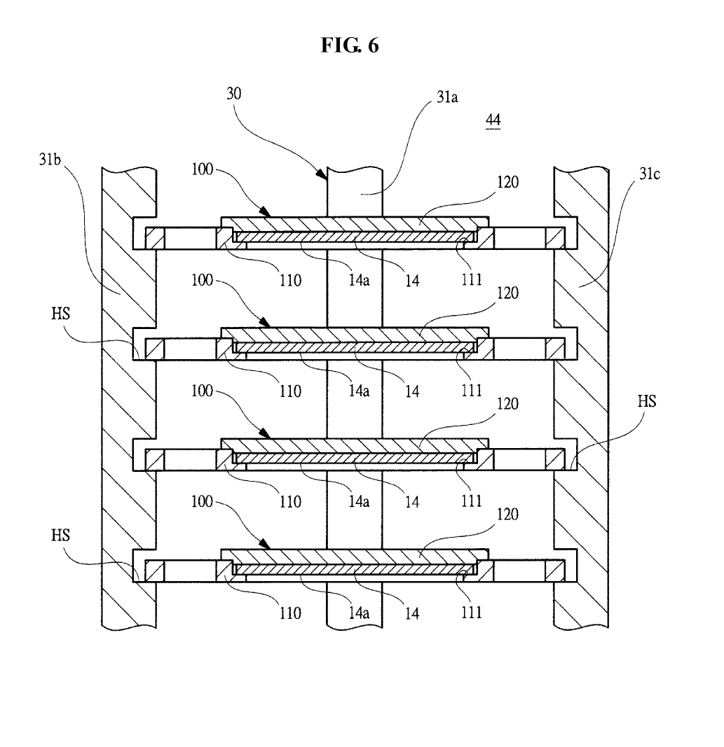

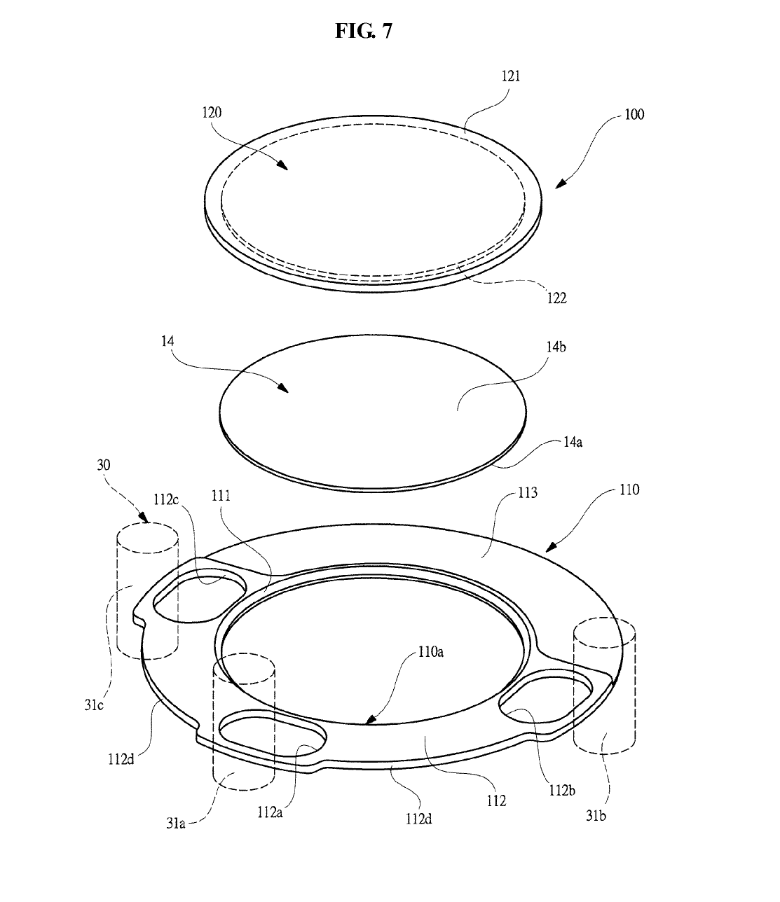

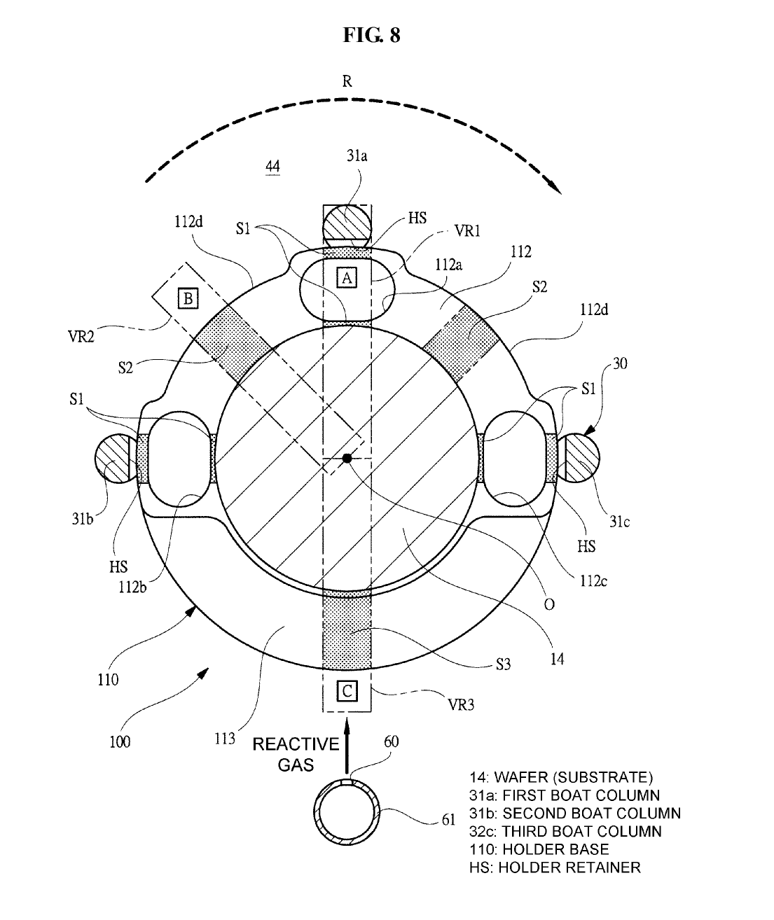

FIG. 2 is a cross-sectional view showing an internal structure of a processing furnace, FIG. 3 is a cross-sectional view showing a peripheral structure of the processing furnace, FIG. 4 is a block diagram for explaining a control system of the substrate processing apparatus, FIG. 5 is a perspective view showing a detailed structure of a boat, FIG. 6 is a cross-sectional view showing a state in which a wafer is held by a wafer holder, FIG. 7 is a perspective view showing the wafer and the wafer holder, and FIG. 8 is a view for explaining consumption of a reactive gas at the wafer holder. Hereinafter, the processing furnace 40 of the semiconductor manufacturing apparatus 10 for forming a SiC epitaxial film will be described with reference to FIGS. 2 to 8.

The processing furnace 40 includes a reaction tube 42 which forms a cylindrical reaction chamber 44. The reaction tube 42 is formed of a heat-resistant material such as quartz or SiC, and has a bottomed cylindrical shape with an upper side closed and a lower side opened. The boat 30 is received into the reaction chamber 44 in the reaction tube 42. Here, the boat 30 holds the wafers 14 mounted on a plurality of wafer holders 100 (see FIGS. 6 to 8) in a state in which the wafers are concentrically aligned in a horizontal posture and longitudinally stacked. In addition, in order for heat from a heating body 48 not to be easily transferred to a lower side of the processing furnace 40, a boat insulating part 34, which is a cylindrical insulating member formed of a heat-resistant material such as quartz or SiC, is installed at a lower side of the boat 30.

A manifold 36 is disposed at an opening side of the reaction tube 42 (a lower side of the drawing) to form a concentric relationship with the reaction tube 42. The manifold 36 is formed of, for example, stainless steel, and has a cylindrical shape with upper and lower sides opened. The manifold 36 supports the reaction tube 42, and an O-ring (not shown), which is a seal member, is installed between the manifold 36 and the reaction tube 42. Accordingly, leakage of a reactive gas filled in the reactive tube 42 and the manifold 36 to the outside is prevented.

The manifold 36 is supported by a retainer (not shown) installed at a lower side thereof, and thus, the reaction tube 42 is in a state in which the reaction tube 42 can be vertically installed with respect to the ground (not shown). Here, the reaction tube 42 and the manifold 36 constitute a reaction vessel.

The processing furnace 40 includes a heating body 48 and an induction coil 50. The heating body 48 is installed in the reaction chamber 44 and has a bottomed cylindrical shape with an upper side closed and a lower side opened. Accordingly, the reactive gas supplied into the heating body 48 can be sealed and radiation toward an upper side of the reaction chamber 44 can be suppressed. The heating body 48 is installed to surround at least a stacking region of the plurality of stacked wafers 14 and induction-heated by the induction coil 50, which functions as a magnetic field generator.

The induction coil 50 is fixed to an inner circumference side of a cylindrical support member 51 in a spiral shape, and the induction coil 50 is energized by an external power source (not shown). In addition, as the induction coil 50 is energized, the induction coil 50 generates a magnetic field, and further, the heating body 48 is induction-heated. As described above, as the heating body 48 is heated by induction-heating, the inside of the reaction chamber 44 is heated.

A temperature sensor (not shown), which is a temperature detector configured to detect a temperature in the reaction chamber 44, is installed adjacent to the heating body 48, and the temperature sensor and the induction coil 50 are electrically connected to a temperature control unit 52 of a controller 152 (see FIG. 4). The temperature control unit 52 adjusts (controls) a conduction state to the induction coil 50 at a predetermined timing such that the temperature in the reaction chamber 44 reaches a predetermined temperature distribution based on the temperature information detected by the temperature sensor.

For example, an insulating material 54 formed of a carbon felt, which cannot be easily induction-heated, is installed between the reaction tube 42 and the heating body 48. The insulating material 54 includes a sidewall portion 54a and a cover portion 54b, and has a bottomed cylindrical shape with an upper side closed and a lower side opened, similar to the reaction tube 42 and the heating body 48. As described above, as the insulating material 54 is installed, transfer of radiant heat from the heating body 48 is blocked and heating of the outside of the reaction tube 42 or the reaction tube 42 is suppressed. In addition, the sidewall portion 54a and the cover portion 54b may be integrally formed with each other or separately formed from each other.

In order to suppress transfer of the heat in the reaction chamber 44 to the outside, for example, an outer insulating wall 55 having a water cooling structure is installed at an outer circumference side of the induction coil 50. The outer insulating wall 55 has a cylindrical shape and is disposed to surround a reaction chamber 44 (a support member 51). In addition, a magnetic seal 58 is installed at an outer circumference side of the outer insulating wall 55 to prevent a magnetic field generated by conduction to the induction coil 50 from being leaked to the outside. The magnetic seal 58 also has a bottomed cylindrical shape with an upper side closed and a lower side open.

A first gas supply nozzle (a gas nozzle) 61 including a plurality of first gas supply ports 60 configured to supply at least a silicon atom-containing gas, a chlorine atom-containing gas, a carbon atom-containing gas and a reducing gas is installed between the heating body 48 and each wafer 14. In addition, a first gas exhaust port 62 configured to exhaust the reactive gas supplied through the first gas supply nozzle 61 to the outside is installed at a position opposite to the first gas supply nozzle 61 between the heating body 48 and each wafer 14. In addition, a second gas supply nozzle 65 including a second gas supply port 64 is installed between the reaction tube 42 and the insulating material 54, and a second gas exhaust port 66 is installed at an opposite position thereof. Hereinafter, each of the nozzles will be described.

The first gas supply nozzle 61 has a hollow pipe shape formed of, for example, carbon graphite, and a front end extending toward an upper side of the heating body 48. Each of the first gas support ports 60 of the first gas supply nozzle 61 is directed toward a side surface of each wafer. A base end side of the first gas supply nozzle 61 passes through the manifold 36 to be fixed to the manifold 36 by welding, etc. The first gas supply nozzle 61 supplies a reactive gas, in which at least a silicon atom-containing gas such as monosilane (SiH₄) gas, a chlorine atom-containing gas such as hydrogen chloride (HCl) gas, a carbon atom-containing gas such as propane (C₃H₈) gas, and a reducing gas such as hydrogen (H₂) gas are mixed, to each wafer 14.

The first gas supply nozzle 61 is connected to a first gas line 68. The first gas line 68 is connected to a first gas source 70a, a second gas source 70b, a third gas source 70c and a fourth gas source 70d via mass flow controllers (MFCs) 72a, 72b, 72c and 72d, which are flow rate controllers (flow rate control units), and valves 74a, 74b, 74c and 74d. In addition, the gas sources 70a to 70d are filled with, for example, SiH₄ gas, HCl gas, C₃H₈ gas and H₂ gas, respectively.

According to the above configuration, supply flow rates, concentrations, partial pressures, and so on, of the SiH₄ gas, HCl gas, C₃H₈ gas and H₂ gas may be controlled. The valves 74a to 74e and the MFCs 72a to 72e are electrically connected to a gas flow rate control unit 78 of the controller 152 (see FIG. 4). The gas flow rate control unit 78 controls a flow rate of each reactive gas, which is to be supplied, to a predetermined flow rate at a predetermined timing. Here, a first gas supply system is constituted by the gas sources 70a to 70d configured to supply SiH₄ gas (a film-forming gas), HCl gas (an etching gas), C₃H₈ gas (a film-forming gas) and H₂ gas (a reducing gas), the valves 74a to 74d, the MFCs 72a to 72d, the first gas line 68, the first gas supply nozzle 61 and the first gas supply ports 60.

In addition, in the above configuration, while at least the silicon atom-containing gas, chlorine atom-containing gas, carbon atom-containing gas and reducing gas are supplied through each of the first gas supply ports 60 of the first gas supply nozzle 61, the gas supply nozzle is not limited thereto but may be individually installed to correspond to the reactive gases. In this case, the reactive gases are mixed in the reaction chamber 44. In addition, for example, two gas supply nozzles may be installed, and among the four kinds of reactive gases, two kinds of gases may be arbitrarily mixed to be supplied to each wafer 14.

Further, while the above configuration exemplifies the case in which HCl gas is used as the chlorine atom-containing gas, chlorine (Cl₂) gas and so on may be used.

Furthermore, in the above configuration, while the silicon atom-containing gas and chlorine atom-containing gas are mixed in the first gas line 68 and the mixed reactive gas is supplied to the wafer 14 through each of the first gas supply ports 60, it is not limited thereto but, for example, tetrachlorosilane (SiCl₄) gas, trichlorosilane (SiHCl₃) gas, dichlorosilane (SiH₂Cl₂) gas, and so on, may be supplied.

In addition, while the above configuration exemplifies the case in which C₃H₈ gas is used as the carbon atom-containing gas, it is not limited thereto but ethylene (C₂H₄) gas, acetylene (C₂H₂) gas, and so on, may be used.

Further, a dopant gas may be mixed in the first gas supply nozzle 61, and a reactive gas including the dopant gas may be supplied through each of the first gas supply ports 60. Furthermore, an exclusive gas supply nozzle configured to supply the dopant gas may be separately provided, and the dopant gas may be supplied into the reaction chamber 44 through the gas supply nozzle.

A gas exhaust pipe 76 passed through the manifold 36 and fixed to the manifold 36 by welding, etc., is connected to the first gas exhaust port 62 opposite to the first gas supply nozzle 61 between the heating body 48 and each wafer 14. Accordingly, the reactive gas supplied into the reaction chamber 44 is discharged to the outside of the semiconductor manufacturing apparatus 10 via the first gas exhaust port 62 and the gas exhaust pipe 76.

As described above, at least the silicon atom-containing gas, chlorine atom-containing gas, carbon atom-containing gas and reducing gas are supplied into the reaction chamber 44 through each of the first gas supply ports 60, the reactive gas supplied through each of the first gas supply ports 60 flows in parallel to each of the wafers 14 stacked on the boat 30 from a lateral direction, and then, the reactive gas is directed to the first gas exhaust port 62. Accordingly, the entire film-forming surface of each wafer 14 can be efficiently and uniformly exposed to the reactive gas.

Here, preferably, a structure (not shown) configured to direct a flow direction of the reactive gas toward each of the wafers 14 between the first gas supply nozzle 61 and the first gas exhaust port 62 may be installed between the heating body 48 and each of the wafers 14 in the reaction chamber 44. The structure may be formed of an insulating material or carbon graphite to improve a heat-resisting property or suppress generation of particles. Accordingly, since the reactive gas supplied through each of the first gas supply ports 60 can be more widely spread to the entire film-forming surface of each of the wafers 14, each of the wafers 14 can be efficiently and uniformly exposed to the reactive gas. Further, film thickness uniformity (film-forming precision) of the SiC epitaxial film formed on each of the wafers 14 can be improved.

A base end side of the second gas supply nozzle 65 disposed between the reaction tube 42 and the insulating material 54 passes through the manifold 36 to be fixed to the manifold 36 by welding, etc. The second gas supply nozzle 65 is connected to a second gas line 69, and the second gas line 69 is connected to a fifth gas source 70e via an MFC 72e and a valve 74e. In addition, the fifth gas source 70e is filled with, for example, an inert gas such as Ar gas, which is a rare gas. Accordingly, introduction of the reactive gas contributing to growth of the SiC epitaxial film between the reaction tube 42 and the insulating material 54 can be prevented, and adhesion of unnecessary byproducts to an inner wall of the reaction tube 42 or an outer wall of the insulating material 54 can be suppressed. In addition, the valve 74e and the MFC 72e are also electrically connected to the gas flow rate control unit 78 of the controller 152 (see FIG. 4).

The second gas exhaust port 66 is installed at an opposite position of the second gas supply nozzle 65 between the reaction tube 42 and the insulating material 54. Similar to the first gas exhaust port 62, the second gas exhaust port 66 is also connected to the gas exhaust pipe 76. A vacuum exhaust apparatus 80 such as a vacuum pump is connected to a downstream side of the gas exhaust pipe 76 via a pressure sensor (not shown), which is a pressure detector, and an automatic pressure controller (APC) valve 79, which is a pressure regulator.

A pressure control unit 98 of the controller 152 (see FIG. 4) is electrically connected to the pressure sensor and the APC valve 79. The pressure control unit 98 adjusts (controls) an opening angle of the APC valve 79 at a predetermined timing based on the pressure detected by the pressure sensor. Accordingly, the Ar gas supplied between the reaction tube 42 and the insulating material 54 is exhausted from the vacuum exhaust apparatus 80 to the outside via the second gas exhaust port 66, the gas exhaust pipe 76 and the APC valve 79 to a predetermined amount so that the pressure in the processing furnace 40 is adjusted to a predetermined pressure.

Here, a second gas supply system is constituted by the fifth gas source 70e configured to supply Ar gas (an inert gas), the valve 74e, the MFC 72e, the second gas line 69, the second gas supply nozzle 65 and the second gas supply port 64. In addition, although the case in which Ar gas is supplied as the inert gas is exemplified, it is not limited thereto but at least one gas of rare gases such as helium (He) gas, neon (Ne) gas, krypton (Kr) gas and xenon (Xe) gas, or a mixed gas of the at least one of the rare gases and the Ar gas may be supplied.

<Peripheral Configuration of Processing Furnace>

As shown in FIG. 3, a seal cap (a furnace port cover) 102 configured to hermetically close a furnace port 144, which is an opening of the processing furnace 40, is installed at a lower side of the processing furnace 40. The seal cap 102 is formed of a metal material such as stainless steel and has substantially a disc shape. An O-ring (not shown), which is a seal member, configured to seal between the seal cap 102 and a top plate 126 of the processing furnace 40 is installed therebetween, and thus, the inside of the processing furnace 40 can be hermetically sealed.

A rotary mechanism 104 is installed at the seal cap 102, and a rotary shaft 106 of the rotary mechanism 104 passes through the seal cap 102 to be coupled to the boat insulating part 34. In addition, as the rotary mechanism 104 is rotated, the boat 30 is rotated in the processing furnace 40 via the rotary shaft 106 and the boat insulating part 34, and thus, the wafer 14 is also rotated.

The seal cap 102 is configured to be raised and lowered in a vertical direction (up/down direction) by an elevation motor (an elevation mechanism) M installed outside the processing furnace 40 so that the boat 30 can be loaded into/unloaded from the processing furnace 40. A drive control unit 108 of the controller 152 (see FIG. 4) is electrically connected to the rotary mechanism 104 and the elevation motor M. The drive control unit 108 controls the rotary mechanism 104 and the elevation motor M to perform a predetermined operation at a predetermined timing.

A load lock chamber LR, which is a preliminary chamber, is installed at a lower side of the processing furnace 40, and a lower base plate LP is installed outside the load lock chamber LR. A base end of a guide shaft 116 configured to slidably support an elevation frame 114 is fixed to the lower base plate LP, and a base end of a ball screw 118 threadedly engaged with the elevation frame 114 is rotatably supported by the lower base plate LP. In addition, an upper base plate UP is mounted on a front end of the guide shaft 116 and a front end of the ball screw 118. The ball screw 118 is rotatably driven by the elevation motor M mounted on the upper base plate UP and the elevation frame 114 is raised and lowered by rotation of the ball screw 118.

An elevation shaft 124 having a hollow pipe shape is fixed to the elevation frame 114 in a vertically downward direction, and a connecting portion between the elevation frame 114 and the elevation shaft 124 is kept hermetically sealed. Accordingly, the elevation shaft 124 is raised and lowered with the elevation frame 114. The elevation shaft 124 passes through a through-hole 126a formed in the top plate 126 over the load lock chamber LR with a predetermined gap. That is, when the elevation shaft 124 is raised and lowered, the elevation shaft 124 does not contact the top plate 126.

A bellows (a hollow flexible body) 128 having flexibility to cover surroundings of the elevation shaft 124 is installed between the load lock chamber LR and the elevation frame 114, and the load lock chamber LR is hermetically sealed by the bellows 128. In addition, the bellows 128 has a sufficient flexibility to correspond to an elevation amount of the elevation frame 114, and an inner diameter of the bellows 128 is sufficiently larger than an outer diameter of the elevation shaft 124. Accordingly, the bellows 128 can be smoothly expanded and contracted upon expansion and contraction thereof, with no contact with the elevation shaft 124.

An elevation plate 130 is horizontally fixed to a lower side of the elevation shaft 124, and a drive part cover 132 is hermetically installed at a lower side of the elevation plate 130 via a seal member such as an O-ring (not shown). The elevation plate 130 and the drive part cover 132 constitute a drive part receiving case 134, and thus, an atmosphere in the drive part receiving case 134 is isolated from an atmosphere in the load lock chamber LR.

The rotary mechanism 104 configured to rotate the boat 30 is installed in the drive part receiving case 134, and surroundings of the rotary mechanism 104 are cooled by a cooling mechanism 135 having a water cooling structure.

A power cable 138 is electrically connected to the rotary mechanism 104, and the power cable 138 is guided to the rotary mechanism 104 from an upper side of the elevation shaft 124 through a hollow portion. In addition, cooling water flow paths 140 are formed in the cooling mechanism 135 and the seal cap 102, respectively, and cooling water pipes 142 are connected to the cooling water flow paths 140, respectively. Each of the cooling water pipes 142 is guided to each of the cooling water flow paths 140 from the upper side of the elevation shaft 124 through the hollow portion.

The elevation motor M is rotated by the drive control unit 108 of the controller 152 to rotate the ball screw 118 so that the elevation frame 114 and the elevation shaft 124 are raised and lowered, and further, the drive part receiving case 134 is raised and lowered. In addition, as the drive part receiving case 134 is raised, the seal cap 102 hermetically installed at the elevation plate 130 seals the furnace port 144, which is an opening of the processing furnace 40, so that the wafer 14 can be thermally processed. Further, as the drive part receiving case 134 is lowered, the boat 30 is lowered with the seal cap 102 so that the wafer 14 can be unloaded to the outside of the processing furnace 40.

As shown in FIG. 4, the controller 152 configured to control the semiconductor manufacturing apparatus 10 for forming a SiC epitaxial film includes the temperature control unit 52, the gas flow rate control unit 78, the pressure regulation part 98 and the drive control unit 108. The temperature control unit 52, the gas flow rate control unit 78, the pressure regulation part 98 and the drive control unit 108 constitute an operation part and an input/output part, and are electrically connected to a main control unit 150 configured to control the entirety of the semiconductor manufacturing apparatus 10.

<Stack Structure of Wafers>

As shown in FIG. 5, the boat 30 includes an upper plate 30a having a disc shape, a lower plate 30b having an annular shape, and boat columns, which are a first boat column 31a, a second boat column 31b and a third boat column 31c, installed between the upper plate 30a and the lower plate 30b and configured to support the plates in a horizontal state. The upper plate 30a, the lower plate 30b and the boat columns 31a to 31c are formed of a heat-resistant material such as SiC, and integrally installed by a fastening method such as press-fitting or screw-fastening.

All of the boat columns 31a to 31c have the same shape, and in a state in which the boat 30 is assembled, a plurality of holder retainers HS formed of cutout portions are formed in an opposite side of each of the boat columns 31a to 31c. The holder retainers HS are configured to separately hold an outer circumference side of the wafer holder 100 (see FIG. 6) on which the wafer 14 is mounted. The holder retainers HS are formed at predetermined intervals in a longitudinal direction of each of the boat columns 31a to 31c, for example, to 30 stages. That is, the boat 30 is configured to stack and hold 30 wafers 14 in the longitudinal direction in a state in which the 30 wafers 14 are concentrically stacked via the wafer holders 100 in a horizontal posture, respectively.

The first boat column 31a and the second boat column 31b are disposed at a 90° interval in a circumferential direction of the upper plate 30a and the lower plate 30b. In addition, the second boat column 31b and the third boat column 31c are disposed at a 180° interval in the circumferential direction of the upper plate 30a and the lower plate 30b. That is, the interval between the first boat column 31a and the second boat column 31b is smaller than that between the second boat column 31b and the third boat column 31c. In addition, the first boat column 31a and the third boat column 31c are disposed at a 90° interval in the circumferential direction of the upper plate 30a and the lower plate 30b, similar to the relationship between the first boat column 31a and the second boat column 31b. The widest opening of the intervals between the boat columns 31a to 31c, i.e., an opening between the second boat column 31b and the third boat column 31c, is an opening (a loading/unloading port) configured to transfer the wafer holder 100 on which the wafer 14 is held.

As shown in FIGS. 6 to 8, the wafer holder 100 on which the wafer 14 is mounted has a disc shape. The wafer holder 100 includes a disc-shaped holder base 110 and a disc-shaped holder cover 120. Here, the holder base 110 and the holder cover 120 are also formed of a heat-resistant material such as SiC. In addition, the holder base 110 constitutes a wafer holder of the present invention, and the holder cover 120 constitutes a cover member of the present invention. As described above, an upper surface 14b of the wafer 14 is covered by the holder cover 120 so that the wafer 14 can be protected from particles (fine dust) dropped from above the wafer 14.

An outer diameter of the holder base 110 constituting the wafer holder 100 is set to be larger than a contour dimension of the wafer 14. A through-hole 110a axially passing through the holder base 110 is formed in a center portion of the holder base 110, and an annular step portion 111 is formed at an inner circumference of the through-hole 110a. The annular step portion 111 holds the wafer 14.

As described above, as the wafer 14 is held on the annular step portion 111 of the holder base 110, the wafer 14 can be precisely positioned (mounted) on the center portion of the holder base, and further, as shown in FIG. 6, the boat columns 31a to 31c can be spaced apart from the wafer 14. In addition, as the wafer 14 is held on the annular step portion 111, the lower surface 14a of the wafer 14, which becomes a film-forming surface, can be exposed to an atmosphere in the reaction chamber 44.

The holder base 110 includes a main body portion 112 and a thin portion 113, and the thin portion 113 is thinner than the other portion of the holder base 110, i.e., the main body portion 112. The main body portion 112 and the thin portion 113 are disposed to oppose each other in a radial direction of the holder base 110. In a state in which the wafer holder 100 is transferred to the boat 30, a first communication hole 112a, a second communication hole 112b and a third communication hole 112c, which pass in a thickness direction of the main body portion 112, i.e., in an axial direction of the wafer holder 100, are formed in the main body portion 112 to correspond to the boat columns 31a to 31c, respectively.

All of the communication holes 112a to 112c have the same shape and are formed in an elongated hole shape in a circumferential direction of the holder base 110. A length dimension of each of the communication holes 112a to 112c in the circumferential direction of the holder base 110 is set to be larger than a width dimension of each of the boat columns 31a to 31c, and meanwhile, a length dimension (a width dimension) of each of the communication holes 112a to 112c in a radial direction of the holder base 110 is set as a large dimension that can obtain at least a minimum strength of the holder base 110. That is, a width dimension of a portion of the main body portion 112 corresponding to each of the boat columns 31a to 31c in the radial direction is set as a small dimension (a small width) that can obtain at least a minimum strength of the holder base 110.

A pair of notch portions 112d configured to reduce the width dimension of the main body portion 112 in the radial direction are formed between the first communication hole 112a (the first boat column 31a) and the second communication hole 112b (the second boat column 31b) in the circumferential direction of the main body portion 112 and between the first communication hole 112a (the first boat column 31a) and the third communication hole 112c (the third boat column 31c) in the radial direction of the main body portion 112. Each of the notch portions 112d has the same shape. A length dimension of each of the notch portions 112d in the circumferential direction of the main body portion 112 is set as a length dimension in which both ends of the notch portion 112d extend to positions reaching each of communication holes 112a to 112c. Here, the communication holes 112a to 112c and the notch portions 112d are installed in consideration of consumption of the reactive gas by the boat columns 31a to 31c, respectively, and their functions will be described below.

The thin portion 113 is disposed between the second boat column 3 lb and the third boat column 31c, and formed by, for example, cutting (a cutting process) a side of the holder base 110 corresponding to an upper surface 14b side opposite to the lower surface 14a of the wafer 14. The thin portion 113 does not include a communication hole or a notch portion like the main body portion 112. In addition, a thickness dimension of the thin portion 113 is set as a thickness dimension corresponding to substantially a half of a thickness dimension of the main body portion 112. In this embodiment, for example, the thickness dimension of the main body portion 112 is set to 4 mm, and the thickness dimension of the thin portion 113 is set to 2 mm. In addition, the thickness dimension of the wafer 14 is set to, for example, 1 mm.

Here, as the thin portion 113 is provided, a weight balance of the holder base 110 is improved at the main body portion 112 side and the thin portion 113 side with the center of the holder base 110 disposed therebetween. That is, as the weight of the main body portion 112 is reduced by forming the communication holes 112a to 112c and the notch portions 112d in the main body portion 112, the thin portion 113 opposite to the main body portion 112 is thinned to become substantially the same weight as the main body portion 112. Accordingly, the wafer holder 100 on which the wafer 14 is mounted is prevented from being inclined during conveyance thereof or from being shaken on the boat 30.

The holder cover 120 includes a large diameter main body portion 121 and a small diameter fitting portion 122. The small diameter fitting portion 122 enters the annular step portion 111 of the holder base 110 to be mounted thereon. Accordingly, shaking of the holder cover 120 with respect to the holder base 110 is suppressed. The small diameter fitting portion 122 contacts the upper surface (a non-film-forming surface) 14b of the wafer 14 opposite to the lower surface 14a, which is a film-forming surface, with the wafer 14 disposed between the annular step portion 111 and the small diameter fitting portion 122. As described above, as the holder cover 120 is configured to contact the upper surface 14b, the reactive gas (the film-forming gas) does not enter the upper surface 14b so that a film is not formed on the upper surface 14b.

FIG. 8 is a view seen from an upper side, in which the holder cover 120 of the wafer holder 100 is omitted and the wafer 14 is hatched. The wafer holder 100 on which the wafer 14 is mounted is rotated in the reaction chamber 44 in a direction of a dotted arrow R by rotation of the boat 30 according to rotation of the rotary mechanism 104 (see FIGS. 2 and 3). In FIG. 8, in order to describe consumption of the reactive gas by the holder base 110 constituting the wafer holder 100, a first virtual rectangle VR1, a second virtual rectangle VR2 and a third virtual rectangle VR3 (two-dot chain lines in the drawing), which extend from a radial outside of the wafer holder 100 to a center O of the wafer holder 100, are shown. Here, a width dimension of each of the virtual rectangles VR1 to VR3 in a short direction is a width dimension (a diameter dimension) of each of the boat columns 31a to 31c.

The first virtual rectangle VR1 is provided at a portion corresponding to the first boat column 31a, and a surface area of the wafer holder 100 (the holder base 110) at a portion of the first virtual rectangle VR1 is set as a sum S1 (a dotted pattern portion in the drawing). The surface area S1 at the holder base 110 (the main body portion 112) depends upon a size of the first communication hole 112a and is set to a small value.

Here, while FIG. 8 shows the first virtual rectangle VR1 at only the portion corresponding to the first boat column 31a, the same virtual rectangle as the first virtual rectangle VR1 may be shown at portions corresponding to the second boat column 31b and the third boat column 31c. That is, a surface area of the holder base 110 at a virtual rectangle (not shown) of portions corresponding to the second boat column 31b and the third boat column 31c is also set to the sum S1 similar to that mentioned above.

The second virtual rectangle VR2 is provided at a position where the first virtual rectangle VR1 is rotated to a position inclined 45° leftward about the center O of the wafer holder 100 in the drawing, i.e., a middle position between the first boat column 31a and the second boat column 31b. A surface area of the holder base 110 at a portion of the second virtual rectangle VR2 is set to a surface area S2 (a dotted pattern portion in the drawing) larger than the surface area S1 of the portion of the first virtual rectangle VR1. That is, the surface area S1 of the portion of the first virtual rectangle VR1 is smaller than the surface area S2 of the portion of the second virtual rectangle VR2 (S1<S2). While the notch portion 112d is provided at the main body portion 112 corresponding to the portion of the second virtual rectangle VR2, since the width dimension of the first communication hole 112a in the radial direction of the wafer holder 100 provided to correspond to the portion of the first virtual rectangle VR1 is larger than the width dimension of the notch portion 112d in the radial direction of the wafer holder 100, the surface area S2>the surface area S1.

Here, while FIG. 8 shows the second virtual rectangle VR2 only between the first boat column 31a and the second boat column 31b, the same virtual rectangle as the second virtual rectangle VR2 may also be shown between the first boat column 31a and the third boat column 31c. That is, even in the virtual rectangle (not shown) at the middle position between the first boat column 31a and the third boat column 31c, the surface area of the holder base 110 is set to S2 similar to that mentioned above.

The third virtual rectangle VR3 is provided at a position where the first virtual rectangle VR1 is rotated to a position inclined 180° leftward or rightward about the center 0 of the wafer holder 100 in the drawing, i.e., a middle position of the thin portion 113 opposite to the first boat column 31a between the second boat column 31b and the third boat column 31c with the center O disposed therebetween. A surface area of the holder base 110 at a portion of the third virtual rectangle VR3 is set to a surface area S3 (a dotted pattern portion in the drawing) larger than the surface area S2 of the portion of the second virtual rectangle VR2. That is, the surface area S2 of the portion of the second virtual rectangle VR2 is smaller than the surface area S3 of the portion of the third virtual rectangle VR3 (S2<S3).

As described above, provided that the surface area S1 of the portion of the holder base 110 corresponding to each of the boat columns 31a to 31c is S1, the surface area S2 of the holder base 110 between the first boat column 31a and the second boat column 31b and between the first boat column 31a and the third boat column 31c, and the surface area of the holder base 110 between the second boat column 31b and the third boat column 31c is S3, their relationship becomes S1<S2<S3. Accordingly, as shown by an arrow in the drawing, the reactive gas supplied through each of the first gas supply ports 60 of the first gas supply nozzle 61 is consumed at each of the boat columns 31a to 31c and the portion of the surface area S1 (a consumption position A) at the portion corresponding to each of the boat columns 31a to 31c. In addition, the reactive gas is consumed at the portion of the surface area S2 (a consumption position B) between the first boat column 31a and the second boat column 31b and between the first boat column 31a and the third boat column 31c. Further, the reactive gas is consumed at the portion of the surface area S3 (a consumption position C) between the second boat column 31b and the third boat column 31c.

Here, a consumption amount of the reactive gas at each of the consumption positions A to C is balanced such that any one portion becomes substantially the same consumption amount. For example, at the consumption position C, the consumption amount at the portion of the surface area S3 of the holder base 110 becomes 20%, and at the consumption position A, the consumption amount of each of the boat columns 31a to 31c becomes 18% and the consumption amount of the surface area S1 of the holder base 110 becomes 2%. At the consumption position B, it approaches each of the boat columns 31a to 31c in comparison with the consumption position C, and thus, the consumption (the consumption amount 5%) at each of the boat columns 31a to 31c is affected. For this reason, at the consumption position B, the notch portion 112d is formed to finely adjust the consumption amount of the reactive gas (adjust to the consumption amount 15%).

As described above, the consumption amount of the reactive gas at each of the consumption positions A to C can be balanced, i.e., the consumption amount of the reactive gas of the entire portion of each of the consumption positions A to C until arrival at the wafer 14 becomes almost 20%, like the above example, and further, a concentration of the reactive gas until arrival at the wafer 14 may be substantially uniformized. That is, the size of each of the communication holes 112a to 112c and the size of the notch portion 112d in the embodiment may be set in consideration of the consumption amount of the reactive gas as described above.

<Method of Forming SiC Epitaxial Film>

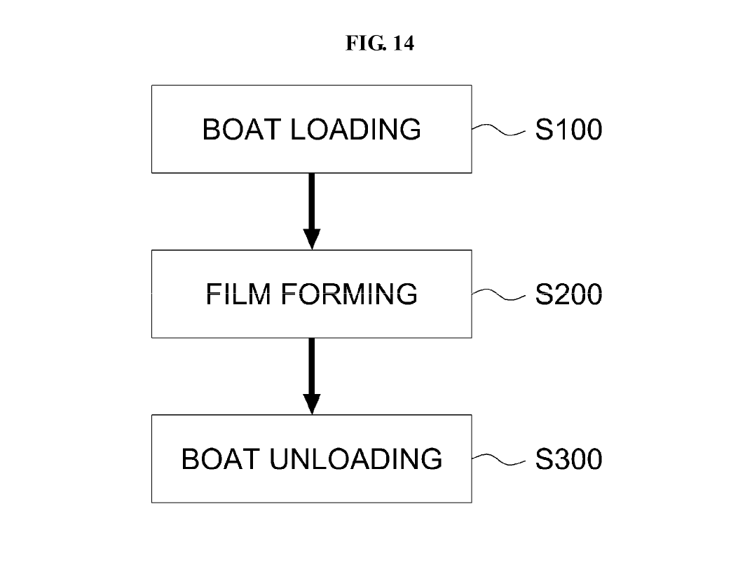

Hereinafter, a method of manufacturing a substrate (a processing method) to form, for example, a SiC epitaxial film on a substrate such as the wafer 14 formed of SiC, which is one of semiconductor device manufacturing processes, using the semiconductor manufacturing apparatus 10, will be described with reference to FIG. 14. FIG. 14 is an exemplary flowchart of a method of manufacturing a semiconductor device in accordance with the present invention. In addition, operations of each element constituting the semiconductor manufacturing apparatus 10 in the following description are controlled by the controller 152.

As shown in FIG. 1, first, the pod 16 in which the plurality of wafers 14 (wafer holders 100) are received is set on the pod stage 18. Then, the pod conveyance apparatus 20 is operated and the pod 16 is conveyed from the pod stage 18 to the pod accommodating shelf 22 to be stocked. Next, the pod conveyance apparatus 20 conveys the pod 16 stocked on the pod accommodating shelf 22 to the pod opener 24 to be set thereto, the pod opener 24 opens the cover 16a of the pod 16, and the substrate number detector 26 detects the number of the wafers 14 received in the pod 16.

Next, the substrate transfer apparatus 28 extracts the wafer holder 100, on which the wafers 14 are mounted, from the pod 16 disposed at a position of the pod opener 24 to transfer the wafer holder 100 to the boat 30.

When the plurality of wafers 14 are stacked on the boat 30, the boat 30 in which the wafers 14 are held is loaded into the reaction chamber 44 by an elevation operation of the elevation frame 114 and the elevation shaft 124 by rotation of the elevation motor M, i.e., the boat is loaded. When the boat 30 is completely loaded into the reaction chamber 44, the seal cap 102 seals the reaction chamber 44, and thus, the reaction chamber 44 is kept hermetically sealed. A series of processes to this point, i.e., processes of loading the plurality of wafers 14 stacked on the boat 30 into the reaction tube 42 (a boat loading process S100) and sealing the reaction chamber 42 by the seal cap 102, constitute a substrate conveyance process.

After the boat 30 is loaded into the reaction chamber 44, the vacuum exhaust apparatus 80 is driven such that the pressure in the reaction chamber 44 arrives at a predetermined pressure (a vacuum degree), and the reaction chamber 44 is vacuum-exhausted (vacuum exhaustion). Here, the pressure in the reaction chamber 44 is measured by the pressure sensor, and the APC valve 79 in communication with the first gas exhaust port 62 and the second gas exhaust port 66 is feedback-controlled based on the measured pressure.

In addition, in order to increase a temperature of the wafer 14 and a temperature in the reaction chamber 44 to a predetermined temperature, the induction coil 50 is energized and thus the heating body 48 is heated. Here, in order for the temperature in the reaction chamber 44 to reach a predetermined temperature distribution (for example, a uniform temperature distribution), a conduction state to the induction coil 50 is feedback-controlled based on temperature information detected by the temperature sensor. Next, the boat 30 is rotated by the rotary mechanism 104, and thus, each of the wafers 14 is also rotated in the reaction chamber 44 (see a dotted arrow R of FIG. 8).

Next, the MFCs 72a to 72d and the valves 74a to 74d are controlled, and thus, a silicon atom-containing gas (a film-forming gas), a chlorine atom-containing gas (an etching gas), a carbon atom-containing gas (a film-forming gas) and H₂ gas (a reducing gas), which contribute to formation of the SiC epitaxial film, are supplied form the gas sources 70a to 70d, respectively. These gases are mixed in the first gas line 68, and then, the reactive gas is injected toward each of the wafers 14 and each of the wafer holders 100 in the reaction chamber 44 through each of the first gas supply ports 60 of the first gas supply nozzle 61 via the first gas line 68.

The reactive gas injected through each of the first gas supply ports 60 is in contact with each of the boat columns 31a to 31c, each of the wafers 14 and each of the wafer holders 100 when passing through the inside of the reaction chamber 44. Accordingly, the SiC epitaxial film is formed on the lower surface 14a (see FIG. 6) of each of the wafers 14, and so on. Next, the reactive gas flows along the inner circumference side of the heating body 48 in the reaction chamber 44 to be exhausted to the outside through the first gas exhaust port 62 via the gas exhaust pipe 76.

In addition, the MFC 72e and the valve 74e are controlled so that Ar gas (a rare gas), which is an inert gas, from the fifth gas source 70e is adjusted to a predetermined flow rate. Then, the Ar gas is supplied between the reaction tube 42 and the insulating material 54 via the second gas line 69, the second gas supply nozzle 65 and the second gas supply port 64. The Ar gas supplied through the second gas supply port 64 flows between the reaction tube 42 and the insulating material 54 to be exhausted to the outside through the second gas exhaust port 66. Next, as described above, when the reactive gas is exposed to each of the wafers 14, and so on, and a predetermined time elapses, supply control of each reactive gas is stopped. A series of processes to this point, i.e., processes of forming the SiC epitaxial film on the lower surface 14a of each of the wafers 14, and so on, by supply of the reactive gas, constitute a substrate processing process (S200).

Next, an inert gas is supplied from an inert gas supply source (not shown), an inner space of the heating body 48 in the reaction chamber 44 is substituted with the inert gas, and the pressure in the reaction chamber 44 returns to a normal pressure.

After the inside of the reaction chamber 44 returns to the normal pressure, the seal cap 102 is lowered by rotation of the elevation motor M, and the furnace port 144 of the processing furnace 40 is opened. Accordingly, each of the thermally processed (film-formed) wafers 14 held on the boat 10 is unloaded from the lower side of the manifold 36 to the outside of the reaction tube 42, i.e., the boat is unloaded (S300). Each of the wafers 14 held on the boat 30 is on standby in the load lock chamber LR until it is cooled.

Next, when each of the wafers 14 is cooled to a predetermined temperature, each of the wafer holders 100 on which each of the wafers 14 is mounted is extracted from the boat 30 by an operation of the substrate transfer apparatus 28, and conveyed to an empty pod 16 set to the pod opener 24 to be received into the pod 16. Next, the pod 16 in which each of the wafers 14 is received is conveyed to the pod accommodating shelf 22 or the pod stage 18 by an operation of the pod conveyance apparatus 20. As a result, a series of operations of the semiconductor manufacturing apparatus 10 is completed.

<Comparison of Film-Forming States>

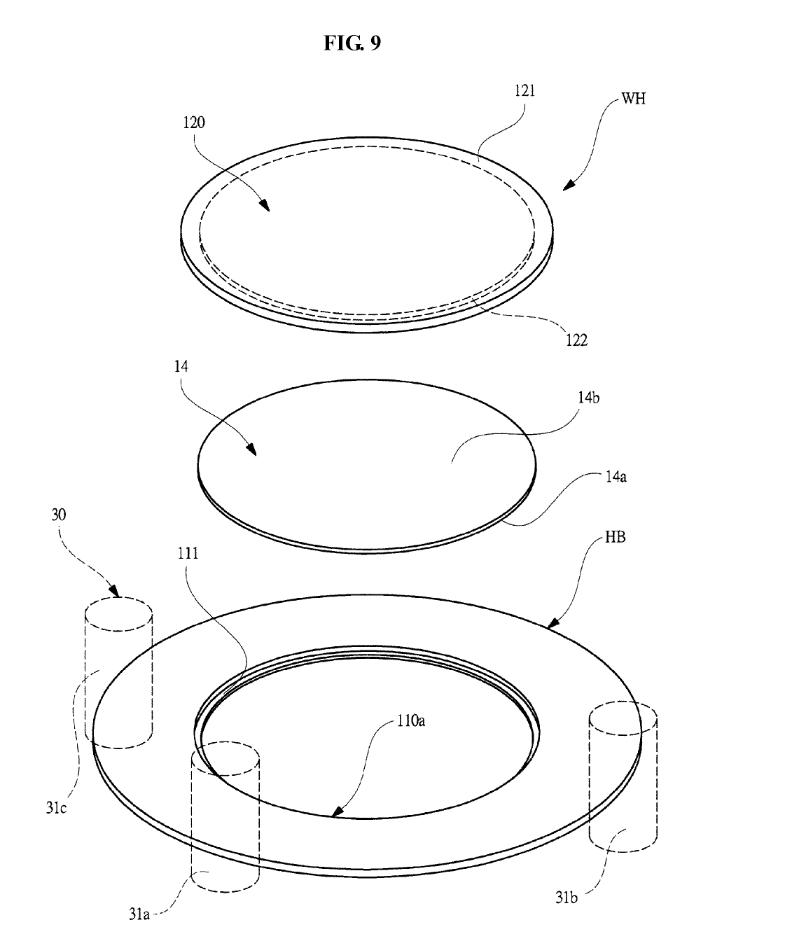

Hereinafter, comparison results of the film-forming state of the SiC epitaxial film when the wafer holder 100 is used (the present invention) and a film-forming state of a SiC epitaxial film when a wafer holder WH having a simple annular shape shown in FIG. 9 is used (Comparative example) will be described in detail with reference to the accompanying drawings.

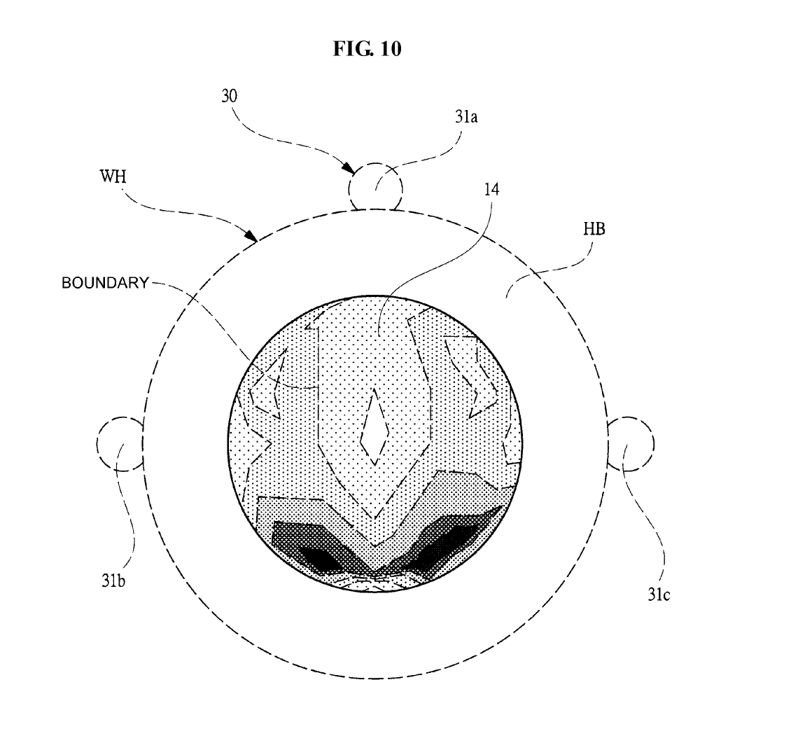

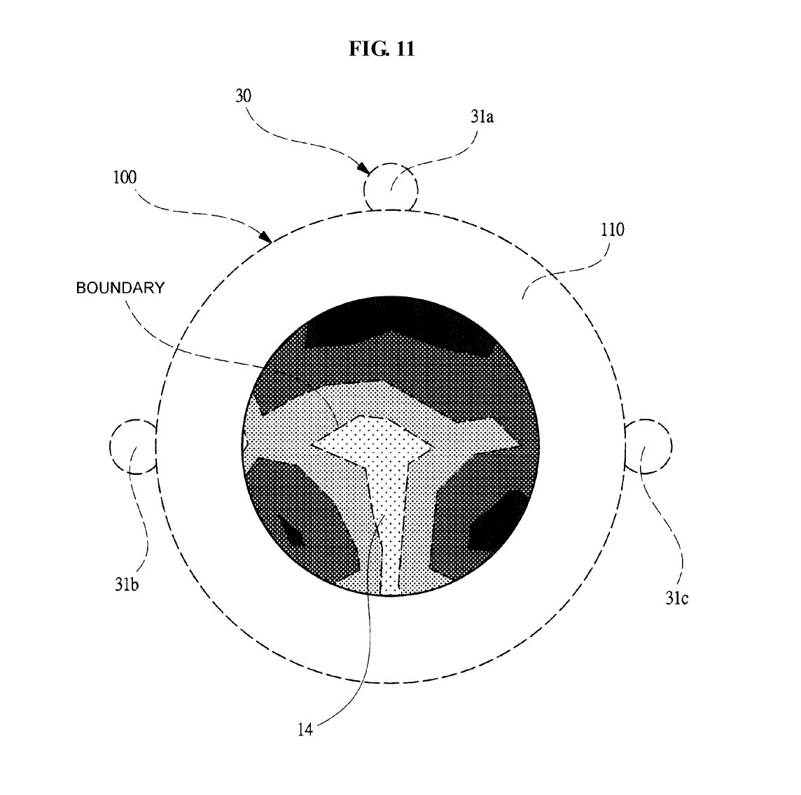

FIG. 9 is a perspective view showing the wafer holder having a simple annular shape (Comparative example), corresponding to FIG. 7, FIG. 10 is an analysis view showing the film-forming state of the wafer using the wafer holder in accordance with Comparative example of FIG. 9, and FIG. 11 is an analysis view showing the film-forming state of the wafer using the wafer holder in accordance with the present invention.

As shown in FIG. 9, the wafer holder WH in accordance with Comparative example is distinguished from the first embodiment in that a shape of a holder base HB is varied. The holder base HB has a simple annular shape with a uniform thickness in the entire circumference and no uneven portion, so that there is no communication hole corresponding to each of the boat columns 31a to 31c and no corresponding notch portion between the boat columns 31a to 31c. That is, the wafer holder WH of Comparative example merely separates the wafer 14 from each of the boat columns 31a to 31c to obtain a certain level of film-forming precision. In addition, in FIG. 9, since the wafer holder has the same elements as the first embodiment other than the shape of the holder base HB, like reference numerals designate like elements.

As shown in FIG. 10, according to the holder base HB, the SiC epitaxial film having a desired film thickness is partially formed at a portion of the wafer 14 between the second boat column 3 lb and the third boat column 31c, i.e., portions that cannot be easily affected by each of the boat columns 31b and 31c (dark portions in the drawing). However, since each of the boat columns 31a to 31c or the holder base HB consumes the reactive gas, the SiC epitaxial film is thin in the other portions of the wafer 14 (light portions in the drawing). In addition, gaps between boundaries of the dark portions in the drawing and the light portions in the drawing are filled and steeply sloped. This means a large difference between concave and convex portions of the film-forming surface of the wafer 14, which may cause a product error in a semiconductor device.

In this regard, according to the holder base 110 of the first embodiment, since the consumption amount of the reactive gas is adjusted (controlled) at the portions other than the portions that cannot be easily affected by each of the boat columns 31b and 31c, as shown in FIG. 11, almost all of the film-forming surface in the wafer 14 can have a desired film thickness (the dark portions of the drawing can be increased). In addition, unlike Comparative example, gaps between boundaries of the dark portions in the drawing and the light portions in the drawing are widened and gently sloped. This means a small difference between concave and convex portions of the film-forming surface of the wafer 14, which may reduce a product error in a semiconductor device.

<Typical Effects of First Embodiment>

According to the technical spirit described in the first embodiment, at least one effect of the plurality of effects described below is obtained.

(1) According to the first embodiment, since each of the boat columns 31a to 31c including the wafer holder 100 (the holder base 110) configured to hold the wafer 14 at the inner circumference side thereof and the holder retainers HS configured to hold the outer circumference side of the holder base 110 are provided, the outer diameter of the holder base 110 is larger than that of the wafer 14, and the holder base 110 is detachable from the holder retainer HS, the holder base 110 and each of the boat columns 31a to 31c are completely fixed with no welding. Accordingly, since the holder base 110 and each of the boat columns 31a to 31c may be formed of SiC, etc., the stack structure of the wafers that can easily endure a high temperature can be realized. In addition, since the wafer 14 is detachable from each of the boat columns 31a to 31c by the holder base 110, bad influence on the film-forming precision can be suppressed.

(2) According to the first embodiment, the surface area S1 of the holder base 110 at the first virtual rectangle VR1 extending to the center O of the holder base 110 in the width dimension of the first boat column 31a is smaller than the surface area S2 of the holder base 110 at the second virtual rectangle VR2 in which the first virtual rectangle VR1 is rotated to the middle position of the first and second boat columns 31a and 31b among the boat columns 31a to 31c about the center O of the holder base 110. Accordingly, since the holder base 110 can be formed in consideration of consumption of the reaction gas by the first boat column 31a, the concentration of the reactive gas arriving at the wafer 14 can be substantially uniformized in the entire circumference thereof. Accordingly, the film-forming precision can be further improved.

(3) According to the first embodiment, the interval between the first and second boat columns 31a and 31b is smaller than that between the second and third boat columns 31b and 31c, the second virtual rectangle VR2 is disposed at the middle position between the first and second boat columns 31a and 31b, and the surface area S2 of the holder base 110 at the second virtual rectangle VR2 is smaller than the surface area S3 of the holder base 110 at the third virtual rectangle VR3 in which the first virtual rectangle VR1 is rotated to the middle position between the second and third boat columns 31b and 31c about the center O of the holder base 110. Accordingly, consumption of the reactive gas by the first and second boat columns 31a and 31b at the small width side can be considered. As a result, concentration of the reactive gas arriving at the wafer 14 can be further uniformized at the entire circumference, and the film-forming precision can be further improved.

(4) By using the semiconductor manufacturing apparatus 10 described in the first embodiment in the substrate processing process of the method of manufacturing a semiconductor device, the method of manufacturing a semiconductor device has at least one effect of the plurality of aforementioned effects.

(5) As the semiconductor manufacturing apparatus 10 described in the first embodiment is used in the substrate processing process of the method of manufacturing a substrate to form the SiC epitaxial film, the method of manufacturing a substrate to form the SiC epitaxial film has at least one effect of the plurality of aforementioned effects.

### Second Embodiment

Hereinafter, a second embodiment of the present invention will be described with reference to the accompanying drawings. In addition, like elements in the first embodiment are designated by like reference numerals and detailed description thereof will not be repeated.

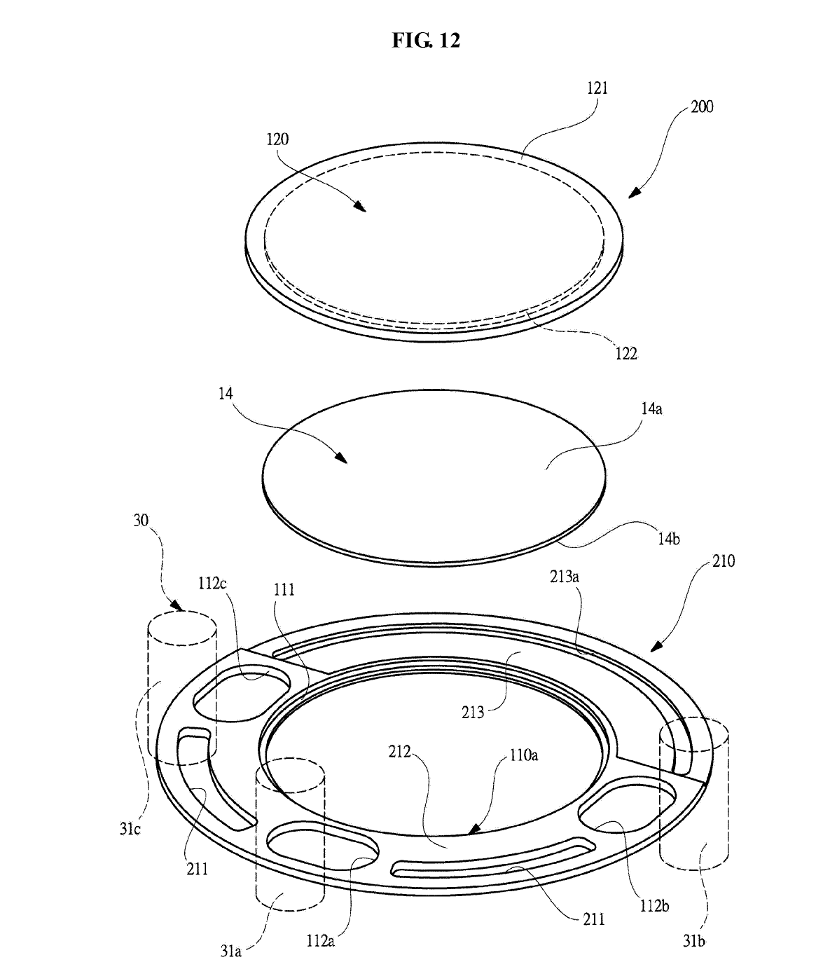

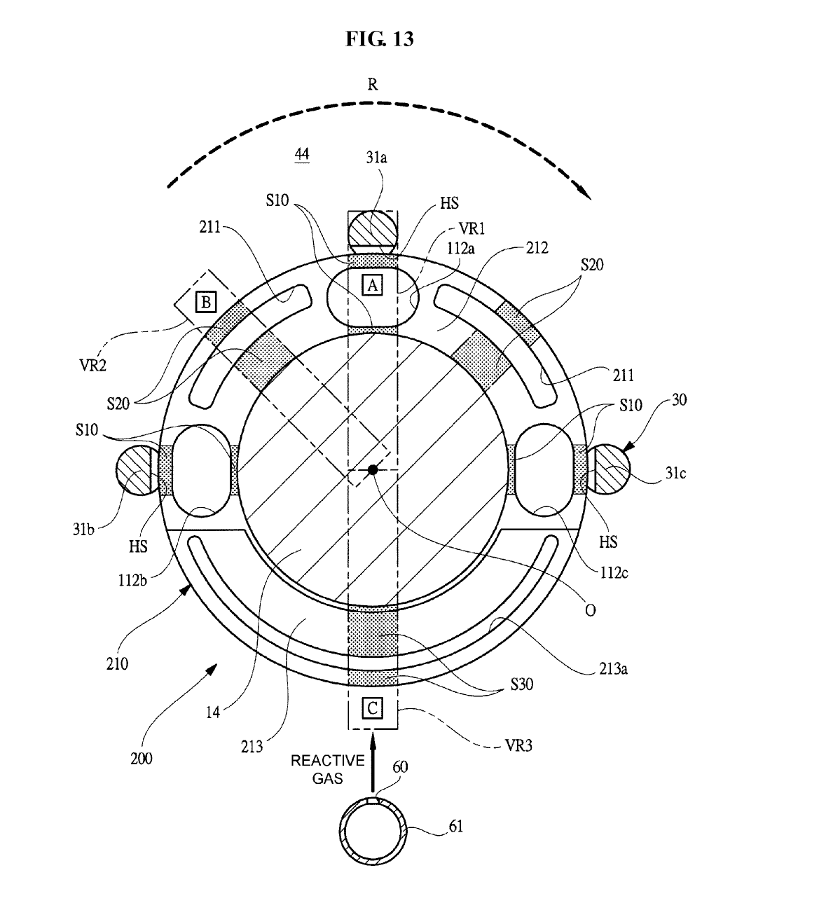

FIG. 12 is a perspective view showing a wafer holder in accordance with the second embodiment, corresponding to FIG. 7 and FIG. 13 is a view for explaining consumption of a reactive gas at the wafer holder of FIG. 12.

The second embodiment is distinguished from the first embodiment in that a shape of a holder base 210 constituting the wafer holder 200 is varied. That is, in the first embodiment, the pair of notch portions 112d (see FIG. 7) are installed at the holder base 110 and the outer circumference side thereof has a non-circular shape; whereas, in the second embodiment, no notch portion 112d is installed at the holder base 210 and the outer circumference side thereof has a circular shape. The holder base 210 includes a pair of discharge holes 211 instead of the notch portions 112d, and each of the discharge holes 211 has the same function as each of the notch portions 112d. The discharge holes 211 are installed between the first boat column 31a and the second boat column 31b and between the first boat column 31a and the third boat column 31c, respectively, and pass through a main body portion 212 of the holder base 210 in an axial direction of the wafer holder 200.

Since the discharge holes 211 (the second embodiment) are disposed inside the notch portions 112d (the first embodiment) in the radial direction, in order for a surface area S20 (see FIG. 13) of a portion of a second virtual rectangle VR2 of the holder base 210 to be substantially equal to the surface area S2 shown in FIG. 8, a width dimension of each of the discharge holes 211 in the radial direction is larger than that of each of the notch portions 112d in the radial direction. Accordingly, a weight of the holder base 210 at the main body portion 212 side is smaller than that of the holder base 110 at the main body portion 112 side shown in FIG. 8. Therefore, in order to keep a balance between the weight of the main body portion 212 and the weight of a thin portion 213 with the center O of the holder base 210 interposed therebetween, an arc-shaped hole 213a is formed in the thin portion 213. The arc-shaped hole 213a is formed to pass through the thin portion 213 of the holder base 210 in the axial direction of the wafer holder 200.

Here, since a surface area S30 of a portion of a third virtual rectangle VR3 of the holder base 210 is slightly smaller than the surface area S3 shown in FIG. 8, the surface areas S10 and S20 of the portions of the first and second virtual rectangles VR1 and VR2 are also set to be slightly smaller than the surface areas S1 and S2 shown in FIG. 8. Accordingly, concentration of the reactive gas arriving at each of the wafers is substantially uniformized in the entire circumference thereof like the first embodiment. In addition, a film thickness state of the wafer 14 by the wafer holder 200 of the second embodiment has substantially the same result as the first embodiment as shown in FIG. 11.

<Typical Effects of Second Embodiment>

Even in the technical spirit described in the second embodiment, the same operational effects as the first embodiment will be provided. In addition, in the second embodiment, since the discharge holes 211 in the axial direction of the wafer holder 200 (the holder base 210) are formed between the first boat column 31a and the second boat column 31b and between the first boat column 31a and the third boat column 31c, respectively, the outer circumference side of the holder base 210 may have a circular shape. Accordingly, distortion of a flow direction of the reactive gas supplied through the first gas supply port 60 of the first gas supply nozzle 61 can be suppressed, and supply of the reactive gas to each of the wafers 14 can be further stabilized.

While the invention conceived of by the inventor has been specifically described based on the embodiments, the present invention is not limited to the above-mentioned embodiments but may be variously varied without departing from the spirit of the invention. For example, while the embodiments have exemplarily described the film-forming apparatus (the substrate processing apparatus) to form the SiC epitaxial film, the technical sprit of the present invention is not limited thereto but may be applied to another type of substrate processing apparatus.

The present invention includes at least the following embodiments.

[Supplementary Note 1]

A substrate processing apparatus including: a reaction vessel; a gas nozzle installed in the reaction vessel and configured to supply a reactive gas into the reaction vessel; a boat including a plurality of boat columns having holder retainers, the boat being configured to be loaded into and unloaded from the reaction vessel; and a wafer holder held by the holder retainers, an inner circumference side of the wafer holder supporting a substrate, wherein an outer diameter of the wafer holder is larger than that of the substrate and the wafer holder is detachable from the holder retainers.

[Supplementary Note 2]

The substrate processing apparatus according to Supplementary Note 1, wherein a surface area of a portion of the wafer holder corresponding to a first virtual rectangle having substantially the same width as a width of each of the plurality of boat columns and extending from an outside of the wafer holder in a radial direction thereof to a center of the wafer holder is smaller than that of a portion of the wafer holder corresponding to a second virtual rectangle in which the first virtual rectangle is rotated to a middle position between the two boat columns among the plurality of boat columns about the center of the wafer holder.

[Supplementary Note 3]

The substrate processing apparatus according to Supplementary Note 2, wherein the plurality of boat columns include first, second and third boat columns, an interval between the first and second boat columns is smaller than that between the second and third boat columns, the second virtual rectangle is disposed at a middle position between the first and second boat columns, and the surface area of the portion of the wafer holder corresponding to the second virtual rectangle is smaller than that of a portion of the wafer holder corresponding to a third virtual rectangle in which the first virtual rectangle is rotated to a middle position between the second and third boat columns about the center of the wafer holder.

[Supplementary Note 4]

The substrate processing apparatus according to Supplementary Note 3, wherein the wafer holder includes a notch portion formed at an outer circumference side of the wafer holder in a radial direction of the wafer holder between the first and second boat columns.

[Supplementary Note 5]

The substrate processing apparatus according to Supplementary Note 3, wherein the outer circumference side of the wafer holder has a circular shape, and the wafer holder includes a discharge hole formed in an axial direction of the wafer holder between the first boat column and the second boat column.

[Supplementary Note 6]

The substrate processing apparatus according to Supplementary Note 2, wherein a thickness of a portion of the wafer holder between the second and third boat columns is smaller than that of the wafer holder in portions other than the portion between the second and third boat columns.

[Supplementary Note 7]

The substrate processing apparatus according to Supplementary Note 6, wherein the wafer holder includes a thin portion formed by cutting a portion of the wafer holder opposite to a film-forming surface of the substrate and having a reduced thickness of the wafer holder.

[Supplementary Note 8]

The substrate processing apparatus according to any one of Supplementary Notes 1 to 7, wherein the wafer holder includes a through-hole formed in the inner circumference side of the wafer holder and configured to pass through the wafer holder in the axial direction thereof, and a cover member mounted on the wafer holder and configured to cover a side of the substrate opposite to the film-forming surface.

[Supplementary Note 9]

The substrate processing apparatus according to Supplementary Note 8, wherein the wafer holder includes a communication hole having substantially the same width as a width of each of the plurality of boat columns, formed in a portion corresponding to the first virtual rectangle extending from a radial outside of the wafer holder to the center of the wafer holder, and formed in the axial direction of the wafer holder.

What is claimed is:

1. A substrate processing apparatus comprising:
a reaction vessel;
a gas nozzle installed in the reaction vessel and configured to supply a reactive gas into the reaction vessel;
a boat including a plurality of boat columns having holder retainers, the boat being configured to be loaded into and unloaded from the reaction vessel; and
a wafer holder held by the holder retainers, an inner circumference side of the wafer holder supporting a substrate, wherein an outer diameter of the wafer holder is larger than that of the substrate and the wafer holder is detachable from the holder retainers.

2. The substrate processing apparatus according to claim 1, wherein a surface area of a portion of the wafer holder corresponding to a first virtual rectangle having substantially a same width as that of each of the plurality of boat columns and extending from an outside of the wafer holder in a radial direction thereof to a center of the wafer holder is smaller than that of a portion of the wafer holder corresponding to a second virtual rectangle in which the first virtual rectangle is rotated to a middle position between the two boat columns among the plurality of boat columns about the center of the wafer holder.

3. The substrate processing apparatus according to claim 2, wherein the plurality of boat columns comprise first, second and third boat columns,
an interval between the first and second boat columns is smaller than that between the second and third boat columns,
the second virtual rectangle is disposed at a middle position between the first and second boat columns, and
the surface area of the portion of the wafer holder corresponding to the second virtual rectangle is smaller than that of a portion of the wafer holder corresponding to a third virtual rectangle in which the first virtual rectangle is rotated to a middle position between the second and third boat columns about the center of the wafer holder.

4. The substrate processing apparatus according to claim 3, wherein the wafer holder comprises a notch portion formed at an outer circumference side of the wafer holder in a radial direction of the wafer holder between the first and second boat columns.

5. The substrate processing apparatus according to claim 3, wherein the outer circumference side of the wafer holder has a circular shape, and
the wafer holder comprises a discharge hole formed in an axial direction of the wafer holder between the first boat column and the second boat column.

6. The substrate processing apparatus according to claim 2, wherein a thickness of a portion of the wafer holder between the second and third boat columns is smaller than that of the wafer holder in portions other than the portion between the second and third boat columns.

7. The substrate processing apparatus according to claim 6, wherein the wafer holder comprises a thin portion formed by cutting a portion of the wafer holder opposite to a film-forming surface of the substrate and having a reduced thickness of the wafer holder.

8. The substrate processing apparatus according to claim 1, wherein the wafer holder comprises:
a through-hole formed in the inner circumference side of the wafer holder and configured to pass through the wafer holder in an axial direction thereof, and
a cover member mounted on the wafer holder and configured to cover a side of the substrate opposite to a film-forming surface.

9. The substrate processing apparatus according to claim 8, wherein the wafer holder comprises a communication hole having substantially a same width as that of each of the plurality of boat columns, formed in a portion corresponding to a first virtual rectangle extending from a radial outside of the wafer holder to the center of the wafer holder, and formed in the axial direction of the wafer holder.

10. A wafer holder transferred to a boat including a plurality of boat columns having holder retainers to be held by the holder retainers, and configured to hold a substrate at an inner circumference side thereof,
wherein an outer diameter of the wafer holder is larger than that of the substrate and the wafer holder is detachable from the holder retainers.

11. The wafer holder according to claim 10, wherein a surface area of a portion of the wafer holder corresponding to a first virtual rectangle having substantially a same width as that of each of the plurality of boat columns and extending from an outside of the wafer holder in a radial direction thereof to a center of the wafer holder is smaller than that of a portion of the wafer holder corresponding to a second virtual rectangle in which the first virtual rectangle is rotated to a middle position between the two boat columns among the plurality of boat columns about the center of the wafer holder.

12. The wafer holder according to claim 11, wherein the plurality of boat columns comprise first, second and third boat columns,
an interval between the first and second boat columns is smaller than that between the second and third boat columns,
the second virtual rectangle is disposed at a middle position between the first and second boat columns, and
the surface area of the portion of the wafer holder corresponding to the second virtual rectangle is smaller than that of a portion of the wafer holder corresponding to a third virtual rectangle in which the first virtual rectangle is rotated to a middle position between the second and third boat columns about the center of the wafer holder.

13. A method of manufacturing a semiconductor device using a substrate processing apparatus including a reaction vessel; a gas nozzle installed in the reaction vessel and configured to supply a reactive gas into the reaction vessel; a boat including a plurality of boat columns having holder retainers, the boat being configured to be loaded into and unloaded from the reaction vessel; and a wafer holder held by the holder retainers, an inner circumference side of the wafer holder supporting a substrate, wherein an outer diameter of the wafer holder is larger than that of the substrate and the wafer holder is detachable from the holder retainers, the method comprising:
loading the boat, in which the wafer holder holding the substrate is held by the holder retainers, into the reaction vessel;
supplying the reactive gas into the reaction vessel through the gas nozzle to form a film on a surface of the substrate; and
unloading the boat from the reaction vessel,
wherein an outer diameter of the wafer holder is larger than that of the substrate, and the wafer holder is detachable from the holder retainers.

14. The method according to claim 13, wherein a surface area of a portion of the wafer holder corresponding to a first virtual rectangle having substantially a same width as that of each of the plurality of boat columns and extending from an outside of the wafer holder in a radial direction thereof to a center of the wafer holder is smaller than that of a portion of the wafer holder corresponding to a second virtual rectangle in which the first virtual rectangle is rotated to a middle position between the two boat columns among the plurality of boat columns about the center of the wafer holder.

15. The method according to claim 14, wherein the plurality of boat columns comprise first, second and third boat columns,
an interval between the first and second boat columns is smaller than that between the second and third boat columns,
the second virtual rectangle is disposed at a middle position between the first and second boat columns, and
the surface area of the portion of the wafer holder corresponding to the second virtual rectangle is smaller than that of a portion of the wafer holder corresponding to a third virtual rectangle in which the first virtual rectangle is rotated to a middle position between the second and third boat columns about the center of the wafer holder.
